(19) United States
(12) Patent Application Publication
(10) Pub. No.: US 2009/0092469 A1
(43) Pub. Date: Apr. 9, 2009

(54) SUBSTRATE PROCESSING UNIT, SUBSTRATE TRANSFER METHOD, SUBSTRATE CLEANSING PROCESS UNIT, AND SUBSTRATE PLATING APPARATUS

(75) Inventors: Masahiko Sekimoto, Tokyo (JP); Toshio Yokoyama, Tokyo (JP); Teruyuki Watanabe, Tokyo (JP); Kenichi Suzuki, Tokyo (JP); Kenichi Kobayashi, Tokyo (JP); Ryo Kato, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EBARA CORPORATION, Tokyo (JP)

(21) Appl. No.: 11/996,432

(22) PCT Filed: Aug. 25, 2006
(86) PCT No.: PCT/JP2006/317284

§ 371 Date: Oct. 10, 2008

(30) Foreign Application Priority Data
Aug. 29, 2005 (JP) 2005-248308

(51) Int. Cl. H01L 21/677; B08B 7/00; C25D 17/06

(52) U.S. Cl. 414/225.01; 134/137; 204/194

(57) ABSTRACT

To provide a substrate processing unit, a substrate transfer method, a substrate cleansing process unit, and a substrate plating apparatus that make it possible for a substrate carry-in mechanism such as a robot arm to quickly release hold on the substrate after carrying in the substrate so as to shorten the time for holding the substrate and improve throughput. The substrate processing unit 10 includes a substrate holding mechanism 10 for holding the substrate 11 in a specified holding position, and a processing mechanism 32 for applying a specified process to the substrate held with the substrate holding mechanism in which a substrate guide mechanism 20 is provided with a guide pin 15 for guiding the substrate to vicinity of a holding position. The substrate holding mechanism has a plural number of rollers 14 on an outer periphery of the holding position of the substrate, with the plural number of rollers adapted to hold the substrate by supporting the periphery of the substrate from sides thereof in the vicinity of the holding position, and the roller has an integral structure made up of a large diameter portion and a small diameter portion formed above the large diameter portion, with an upper portion of the large diameter portion having a shoulder portion for the substrate in transfer to be temporarily placed on, and with the shoulder portion formed with a sloped surface sloping down toward its periphery.

### TECHNICAL FIELD

This invention relates to a substrate processing unit having a substrate holding mechanism for holding a substrate such as a semiconductor wafer in a specified holding position to apply specified processes with a substrate processing mechanism to the substrate held with the substrate holding mechanism, and to a substrate transfer method for transferring the substrate to and from the substrate processing unit. This invention also relates to a substrate cleansing process unit having the substrate holding mechanism for holding a substrate such as a semiconductor wafer in a specified holding position, and to a substrate plating apparatus having the substrate cleansing process unit.

### BACKGROUND ART

FIG. 1 shows a partial structure of a conventional substrate processing unit of this kind for carrying in, holding, and carrying out a substrate as well as its actions. As shown, the substrate processing unit has a substrate holding mechanism 10 for holding a substrate 11 in a specified holding position. The substrate holding mechanism 10 has a plural number (four in FIG. 1) of rollers 12. As shown in FIG. 2, each roller 12 has an integral structure made up of a small diameter portion 12a and a large diameter portion 12b formed below the small diameter portion 12a. A recess 12c is formed around the border between the small diameter portion 12a and the large diameter portion 12b. The upper end of the large diameter portion 12b is made as a horizontal shoulder portion 12d. The rollers 12 are rotatable by means of a rotary mechanism (not shown).

As shown in FIG. 1 A, a substrate 11 is carried in above the rollers 12 with a substrate carry-in mechanism 13 such as a robot arm. As the substrate carry-in mechanism 13 lowers as shown in FIG. 1B, the substrate 11 lowers to the same position as the recesses 12c of the rollers 12. In this state, as shown in FIG. 1C, the rollers 12 are moved in the directions indicated with arrows A toward the substrate 11, so that the periphery of the substrate 11 engages with the recesses 12c of the rollers 12, and the substrate 11 is supported from its sides in a substrate holding position with the rollers 12. Next, the substrate carry-in mechanism 13 lowers further as shown in FIG. 1D to be apart from the substrate 11. After that, the substrate carry-in mechanism 13 retracts from the substrate holding mechanism 10. This brings about the state shown in FIG. 1(E) in which the substrate 11 is supported from its sides with the four rollers 12 in a specified position.

The substrate 11, in the state of being supported from its sides with the plural number of rollers 12 as described above, undergoes a specified process such as cleansing. When the cleansing process of the substrate 11, for example, is finished, the substrate carry-in mechanism 13 is, as shown in FIG. 1D, moved below the substrate 11 held with the substrate holding mechanism 10. As shown in FIG. 1C, the substrate carry-in mechanism 13 is raised to a position for receiving the substrate 11. The rollers 12 are moved in directions opposite the arrows A. As shown in FIG. 1B, the substrate 11 is placed on the substrate carry-in mechanism 13. As shown in FIG. 1A, the substrate carry-in mechanism 13 is raised and retracted to carry out the substrate 11.

### DISCLOSURE OF INVENTION

### Problems to be Solved by the Invention

One of the important points for improving throughput with the apparatus for applying various process such as cleansing to the substrate such as the semiconductor wafer in the state of being held in specified position is to shorten the time of transferring the substrate. To shorten the transfer time, it is also necessary to improve transfer efficiency by reducing the number of transfer steps and so on. However, as the substrate should be transferred carefully free from shocks and interference from other parts, methods of holding and transferring the substrate should also be improved when reducing the number of transfer steps.

In the conventional steps of carrying in, holding, and carrying out the substrate 11 as shown in FIG. 1, the substrate 11 is carried above the substrate holding mechanism 10 with the substrate carry-in mechanism 13 such as a robot arm in the substrate processing unit as shown in FIG. 1A. Next, as shown in FIG. 1B, the substrate carry-in mechanism 13 is lowered so that the substrate 11 engages with the recesses 12c of the rollers 12. Next, as shown in FIG. 1C, the substrate 11 is supported from its sides with the rollers 12. Next, as shown in FIG. 1D, the substrate carry-in mechanism 13 is further lowered and retracted from the substrate holding mechanism 10. As a result, the substrate carry-in mechanism 13 holds the substrate 11 for a long period of time, that has been a problem in improving throughput by shortening the transfer time of the substrate 11.

This invention has been made in view of the above. Therefore, the object of the invention is to provide a substrate processing unit, a substrate transfer method, a substrate cleansing process unit and a substrate plating apparatus that make it possible to remove the above problem by quickly releasing the substrate carry-in mechanism such as the robot arm from the substrate holding state after the carry-in motion so as to shorten the substrate holding time and to improve throughput.

### Means for Solving the Problem

In order to solve the above problem, a substrate processing unit according to this invention comprises, as shown in FIG. 3 and FIG. 13 for example, a substrate holding mechanism 10 for holding a substrate 11 in a specified position, the substrate holding mechanism 10 having a plural number of rollers 14 on a periphery of the substrate 11 in a holding position, the plural number of rollers 14 being adapted to hold the substrate 11 by supporting the periphery of the substrate 11 from sides thereof in vicinity of the holding position; a processing mechanism 32 for applying a specified process to the substrate 11 held with the substrate holding mechanism 10; and a substrate guide mechanism 20 provided with a guide pin 15 for guiding the substrate 11 to vicinity of the holding position, wherein the roller 14 each has an integral structure made up of a large diameter portion 14b and a small diameter portion 14a formed above the large diameter portion 14b, with an upper portion of the large diameter portion 14b having a shoulder portion 14d for temporarily placing the substrate 11 thereon in transfer of the substrate 11, and the shoulder portion 14d is formed with a sloped surface sloping down toward the periphery of the substrate 11.

In order to solve the above-mentioned problem, a substrate processing unit according to this invention comprises, as shown in FIG. 10 and FIG. 13 for example, a substrate holding mechanism 10 for holding a substrate 11 in a specified position, the substrate holding mechanism 10 having a plural number of rollers 14 on a periphery of the substrate 11 in a holding position, the plural number of rollers 14 being adapted to hold the substrate 11 by supporting the periphery of the substrate 11 from sides thereof in vicinity of the holding position; a processing mechanism 32 for applying a specified process to the substrate 11 held with the substrate holding mechanism 10; and a substrate guide mechanism 20 provided with a guide pin 15 for guiding the substrate 11 to vicinity of a holding position, a substrate guide mechanism 20 having a temporary placement tool 25 for temporarily placing the substrate 11 thereon in transfer of the substrate 11, wherein the roller 14 each has an integral structure made up of a large diameter portion 14b and a small diameter portion 14a formed above the large diameter portion 14b with an upper portion of the large diameter portion 14b having a shoulder portion 14d formed with a sloped surface sloping down toward periphery of the substrate 11.

In the substrate processing unit according to this invention, as shown in FIG. 4 for example, the substrate 11 may have a disk shape, and the guide pins 15 of the substrate guide mechanism 20 may be placed around the substrate 11 held in the holding position, and may have a function of guiding the substrate 11 to the vicinity of the holding position even if the substrate 11 displaces when being held or released in the above-mentioned substrate processing unit.

In the substrate processing unit according to this invention, as shown in FIG. 4 for example, the upper portion of the guide pin 15 of the substrate guide mechanism 20 may be tapered off to provide a function of adsorbing a displacement of the substrate 11 in transfer thereof in the above-mentioned substrate processing unit.

In the substrate processing unit according to this invention, as shown in FIG. 4 for example, the guide pins 15 of the substrate guide mechanism 20 may be placed in positions apart from the periphery of the substrate 11 to avoid interference with the substrate 11 when the substrate 11 in the holding position is processed in the above-mentioned substrate processing unit.

In the substrate processing unit according to this invention, the rollers 14 are adapted to be rotated with a rotary mechanism, and the substrate 11 is rotated by rotation of the rollers 14.

A substrate transfer method according to this invention for holding a substrate carried in with a substrate carry-in mechanism in a specified holding position and carrying out the substrate after a specified process comprises, as shown in FIG. 5 and FIG. 9 for example, the steps of: guiding the substrate 11 carried in to the vicinity of the holding position with guide pins 15 as the substrate carry-in mechanism 13 lowers; placing the substrate 11 on a temporary placement portion 14d to be released from the substrate carry-in mechanism 13; holding the substrate 11 released from the substrate carry-in mechanism 13 with a plural number of rollers 14 by supporting a periphery of the substrate 11 from sides thereof in the holding position; applying a specified process to the substrate 11 held; releasing the substrate 11 applied the specified process from holding to be placed on the temporary placement portion 14d; and carrying out the substrate 11 placed on the temporary placement portion 14d, wherein the roller 14 each has an integral structure made up of a large diameter portion 14b and a small diameter portion 14a formed above the large diameter portion 14b, and an upper portion of the large diameter portion 14b has a shoulder portion 14d formed with a sloped surface sloping down toward the periphery of the substrate 11, and wherein the substrate 11 placed on the shoulder portion 14d is held and supported from sides thereof as the plural number of rollers 14 move toward the substrate 11, and released and placed on the shoulder portion 14d as the rollers 14 move in the opposite direction.

A substrate cleansing process unit according to this invention comprises, as shown in FIG. 5 and FIG. 13 for example, a plural number of rollers 14 for holding a substrate 11 in a specified holding position, the rollers 14 having an integral structure made up of a large diameter portion 14b and a small diameter portion 14a formed above the large diameter portion 14b, an upper portion of the large diameter portion 14b having a shoulder portion 14d permitting the substrate 11 in transfer to be temporarily placed on, the shoulder portion 14b being formed with a sloped surface sloping down toward a periphery of the substrate 11, to hold the substrate 11 by supporting the periphery of the substrate 11 from sides thereof in vicinity of the holding position; a guide pin 15 for guiding the substrate 11 to the vicinity of the holding position; a cleansing nozzle 32 for supplying cleansing liquid to the substrate 11 held with the rollers 14; and a brush 31 for coming into contact with a surface of the substrate 11 held with the rollers 14.

A substrate plating apparatus according to this invention comprises, as shown in FIG. 18 and FIG. 19 for example, a pre-plating processing and plating unit 48 for applying a pre-plating process and a plating process to a substrate; the substrate cleansing process unit 46 as recited above for cleansing the substrate having undergone the pre-plating process and the plating process with the pre-plating processing and plating unit 48; and a substrate transfer robot 42 for transferring the substrate having undergone the pre-plating process and the plating process from the pre-plating processing and plating unit 48 to the substrate cleansing process unit 46, and carrying out the substrate from the substrate cleansing process unit 46.

### EFFECTS OF THE INVENTION

The substrate processing unit according to the invention is provided with the substrate guide mechanism having a guide pin for guiding the substrate to the vicinity of the holding position. This makes it unnecessary for the substrate carry-in mechanism such as the robot arm to remain holding the substrate carried in until the substrate is carried over to the substrate holding mechanism, so that the substrate carry-in mechanism, after the carry-in motion, can be quickly released from the substrate holding state and used for the next step. Since the substrate after processing is released from being held with the substrate holding mechanism and is in the vicinity of the holding position with the guide pins, the substrate carry-in mechanism can carry out the substrate quickly irrespective of the substrate holding mechanism. Since the substrate holding mechanism is provided with a plural number of rollers in the periphery of the substrate, and the rollers are capable of holding the substrate by supporting the periphery of the substrate from sides thereof in the vicinity of the holding position, the substrate can be supported from sides thereof or released easily by simply moving the rollers toward or away from the substrate. The rollers each has the shoulder portion that can be used to temporarily receive the substrate being transferred. Therefore, the substrate can be carried in and out while using the shoulder portion as a temporary placement table for the substrate without requiring interlock motion between the substrate holding mechanism and the substrate transfer mechanism, and easily and securely. The shoulder portion of the roller is formed with a sloped surface sloping down toward its periphery. Therefore, when the substrate temporarily placed on the shoulder portion is to be supported from sides thereof with the rollers or when the substrate supported from sides thereof with the rollers is to be moved to the shoulder portion, such motion can be made smoothly by simply moving the rollers toward or away from the substrate.

The substrate processing unit according to the invention is provided with the substrate guide mechanism having a guide pin for guiding the substrate to the vicinity of the holding position. This makes it unnecessary for the substrate carry-in mechanism such as the robot arm to remain holding the substrate carried in until the substrate is carried over to the substrate holding mechanism, so that the substrate carry-in mechanism, after the carry-in motion, can be quickly released from the substrate holding state and used for the next step. Since the substrate after processing is released from being held with the substrate holding mechanism and is in the vicinity of the holding position with the guide pins, the substrate carry-in mechanism can carry out the substrate quickly irrespective of the substrate holding mechanism. Since the substrate holding mechanism is provided with a plural number of rollers in the periphery of the substrate, and the rollers are capable of holding the substrate by supporting the periphery of the substrate from sides thereof in the vicinity of the holding position, the substrate can be supported from ides thereof or released easily by simply moving the rollers toward or away from the substrate. Since the substrate guide mechanism is provided with temporary placement tools, the substrate can be carried in and out while using the temporary placement tool as a temporary placement table for the substrate without requiring interlock motion between the substrate holding mechanism and the substrate transfer mechanism, and easily and securely. The shoulder portion of the roller is formed with a sloped surface sloping down toward its periphery. Therefore, when the substrate temporarily placed on the shoulder portion is to be supported from sides thereof with the rollers or when the substrate supported from sides thereof with the rollers is to be moved to the shoulder portion, such motion can be made smoothly by simply moving the rollers toward or away from the substrate.

The guide pins provided around the substrate held in the holding position have the function of guiding the substrate to the vicinity of the holding position even if the substrate displaces when the substrate is held fixedly or released. Therefore, the substrate can be carried in and out easily, accurately and quickly with the substrate carry-in and carry-out mechanisms.

The upper part of the guide pin is tapered off upward to provide the function of absorbing the displacement of the substrate even if the displacement occurs when the substrate is transferred. As the taper of the guide pin corrects the displacement to guide the substrate approximately to the holding position, the substrate settles in the specified holding position. Then, this makes it possible to support the substrate from sides thereof or to hold the substrate with the substrate holding mechanism, quickly and accurately.

As the guide pins of the substrate guide mechanism are located in positions apart from the periphery of the substrate to avoid interference with the substrate, when the substrate in the holding position is to be processed, the guide pins do not stand in the way of the process of the substrate, so that the process is carried out smoothly.

As the rollers are adapted to be rotatable with the rotary mechanism so that the substrate is rotated with the rotation of the rollers, when the substrate is to undergo a cleansing process for example, the entire surface of the substrate is easily processed evenly while the substrate is being rotated.

With the substrate transfer method according to the invention, as the substrate carry-in mechanism lowers, the substrate which is carried in with the substrate carry-in mechanism, is guided with the guide pins of the substrate guide mechanism to the vicinity of the holding position, placed on the substrate temporary placement portion of the substrate holding mechanism, and removed from the substrate carry-in mechanism. After that, the substrate held in the holding position with the substrate holding mechanism undergoes a specified process. As the substrate holding mechanism releases the hold on the substrate, the substrate is placed on the temporary placement portion, and carried out with the substrate carry-out mechanism. The substrate can be carried in and out without requiring interlock motion between the substrate carry-in and carry-out mechanism and the substrate holding mechanism, by the action of only one of the mechanisms. Therefore, the substrate can be carried in and out easily and quickly. Since the substrate holding mechanism is provided with a plural number of rollers in the periphery of the holding position of the substrate, and the rollers are capable of holding the substrate by supporting the periphery of the substrate from sides thereof, the substrate can be supported from sides thereof or released easily by simply moving the rollers toward or away from the substrate. The rollers each has the shoulder portion that can be used to temporarily receive the substrate being transferred. Therefore, the substrate can be carried in and out while using the shoulder portion as a temporary placement table for the substrate without requiring interlock motion between the substrate holding mechanism and the substrate transfer mechanism, and easily and securely. The shoulder portion of the roller is formed with a sloped surface sloping down toward its periphery. Therefore, when the substrate temporarily placed on the shoulder portion is to be supported from sides thereof with the rollers or when the substrate supported from sides thereof with the rollers is to be moved to the shoulder portion, such motion can be made smoothly by simply moving the rollers toward or away from the substrate.

The substrate cleansing process unit according to the invention includes a plural number of rollers for holding a substrate in a specified holding position, the rollers having an integral structure made up of a large diameter portion and a small diameter portion formed above the large diameter portion, the upper portion of the large diameter portion having a shoulder portion permitting the substrate in transfer to be temporarily placed on, the shoulder portion formed with a sloped surface sloping down toward its periphery, to hold the substrate by supporting the periphery of the substrate form sides thereof in vicinity of the holding position, and a guide pin for guiding the substrate to the vicinity of the holding position. Therefore, the substrate carry-in mechanism can be used for the next step by quickly releasing the hold on the substrate that has been carried in. The substrate after processing is released from being held with the substrate holding mechanism and is in the vicinity of the holding position with the guide pins, the substrate carry-in mechanism can quickly carry out the substrate irrespective of the substrate holding mechanism. The substrate holding mechanism is provided with a plural number of rollers in the periphery of the holding position of the substrate. The rollers are adapted to be capable of holding the substrate by supporting the periphery of the substrate from sides thereof in the vicinity of the holding position. Therefore, the substrate can be supported from sides thereof or released easily by simply moving the rollers toward or away from the substrate. The rollers each has the shoulder portion that can be used to temporarily receive the substrate being transferred. Therefore, the substrate can be carried in and out while using the shoulder portion as a temporary placement table for the substrate without requiring interlock motion between the substrate holding mechanism and the substrate transfer mechanism, and easily and securely. The shoulder portion of the roller is formed with a sloped surface sloping down toward its periphery. Therefore, when the substrate temporarily placed on the shoulder portion is to be supported from sides thereof with the rollers or when the substrate supported from sides thereof with the rollers is to be moved to the shoulder portion, such motion can be made smoothly by simply moving the rollers toward or away from the substrate.

Since the substrate plating apparatus according to the invention is provided with the substrate cleansing process unit described above, the substrate can be quickly carried in and out of the substrate cleansing process apparatus, making the substrate plating apparatus of a high processing efficiency.

### BRIEF DESCRIPTION OF DRAWINGS

FIGS. 1A to 1E show a construction of a conventional substrate processing unit, for its sections for carrying in, holding, and carrying out the substrate; and its actions.

FIG. 2 shows an example structure of the roller of the substrate holding mechanism of the conventional substrate processing unit.

FIGS. 3A and 3B show a construction of a substrate holding mechanism and a substrate carry-in mechanism of a substrate processing unit according to the invention.

FIG. 4 shows a construction of a substrate guide mechanism of the substrate processing unit according to the invention.

FIG. 5 shows a structure of the rollers of the substrate holding mechanism of the substrate processing unit according to the invention.

FIGS. 6A to 6C show the construction and attachment structure of the substrate processing unit according to the invention.

FIG. 7 shows the construction of the substrate guide mechanism of the substrate processing unit according to the invention.

FIG. 8 shows the construction of the substrate guide mechanism of the substrate processing unit according to the invention.

FIGS. 9A to 9D show a construction of a substrate processing unit according to the invention, for its sections for carrying in, holding, and carrying out the substrate; and its actions.

FIGS. 10A and 10B show the construction of the substrate holding mechanism and the substrate carry-in mechanism provided with temporary placement pins according to the invention.

FIGS. 11A to 11C show the construction and attachment structure of the substrate guide mechanism provided with the temporary placement pins according to the invention.

FIG. 12 shows the construction of the substrate guide mechanism of the substrate processing unit provided with the temporary placement pins according to the invention.

FIG. 13 is a plan view showing the planar construction of the substrate processing unit according to the invention.

FIG. 14 is a front view showing the outside appearance construction of the substrate processing unit according to the invention.

FIG. 15 is a side view showing the side face construction of the substrate processing unit according to the invention.

FIG. 16 is a rear view showing the rear face construction of the substrate processing unit according to the invention.

FIG. 17 is an perspective view of the entire structure of the substrate processing unit according to the invention.

FIG. 18 is a plan view showing the planar construction of the substrate processing apparatus provided with the substrate processing unit according to the invention.

FIG. 19 is an perspective view of an example construction of a transfer robot.

FIG. 20 is a side view of an example construction of the transfer robot.

FIGS. 21A and 21B are side views showing an example of drum structure of the transfer robot.

FIG. 22 is a plan view of planar construction of a temporary placement table.

FIG. 23 is a side view of side face construction of the temporary placement table.

### BEST MODE FOR CARRYING OUT THE INVENTION

The basic Japanese Patent Application No. 2005-248308 filed on Aug. 29, 2005 is hereby incorporated in its entirety by reference into the present application.

The present invention will become more fully understood from the detailed description given hereinbelow. The other applicable fields will become apparent with reference to the detailed description given hereinbelow. However, the detailed description and the specific embodiment are illustrated of desired embodiments of the present invention and are described only for the purpose of explanation. Various changes and modifications will be apparent to those ordinary skilled in the art within the spirit and scope of the present invention on the basis of the detailed description.

The applicant has no intention to give to public any disclosed embodiments. Among the disclosed changes and modifications, those which may not literally fall within the scope of the present claims constitute, therefore, a part of the present invention in the sense of doctrine of equivalents.

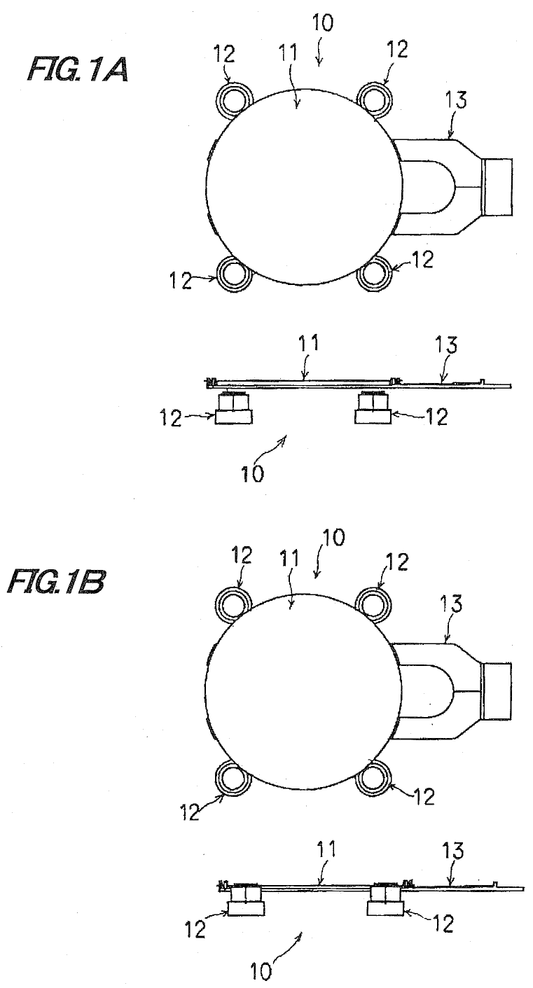

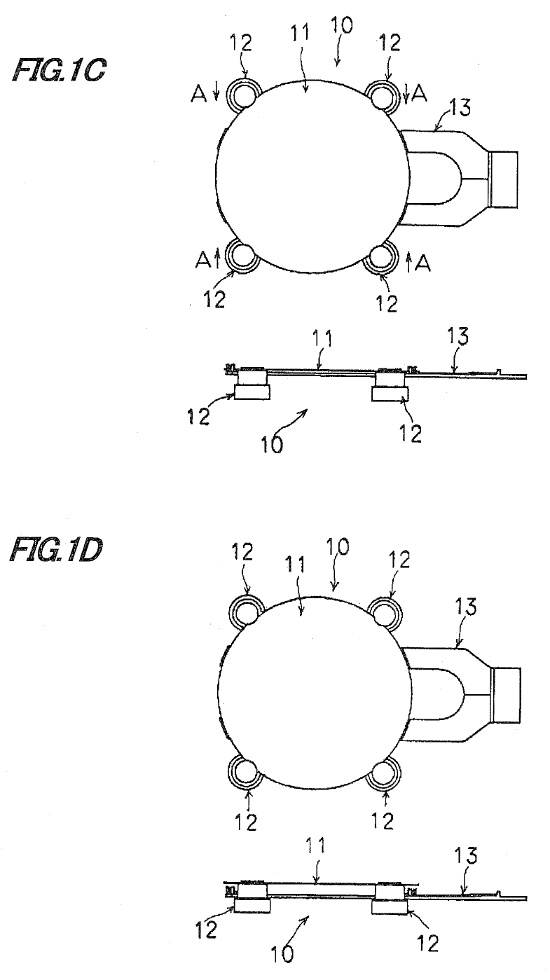

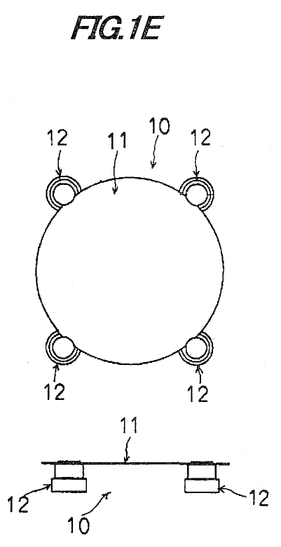

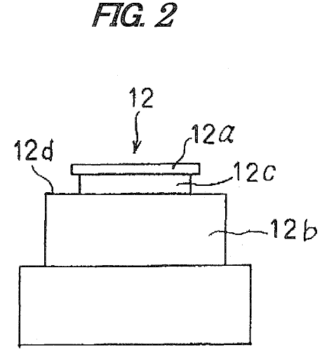

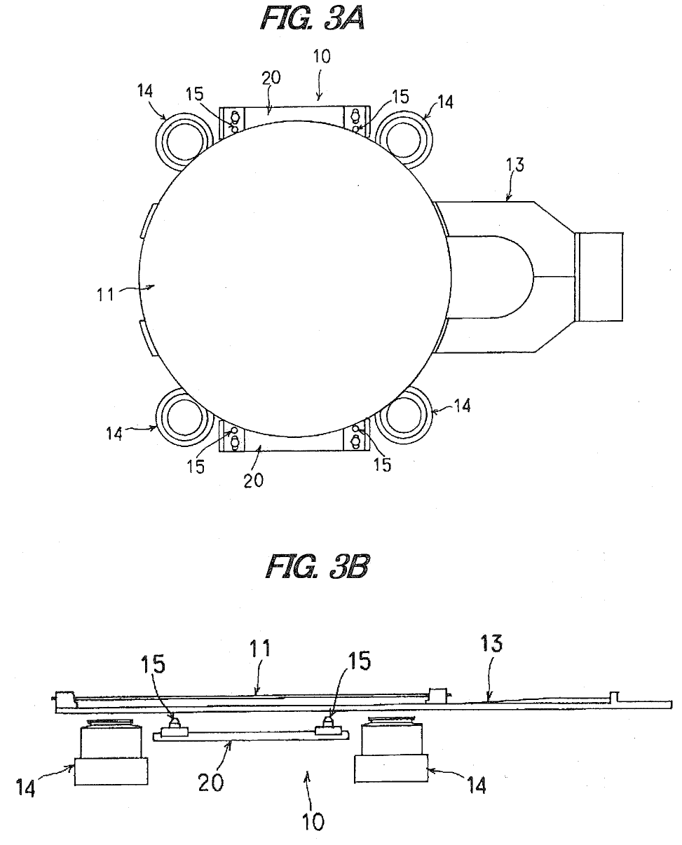

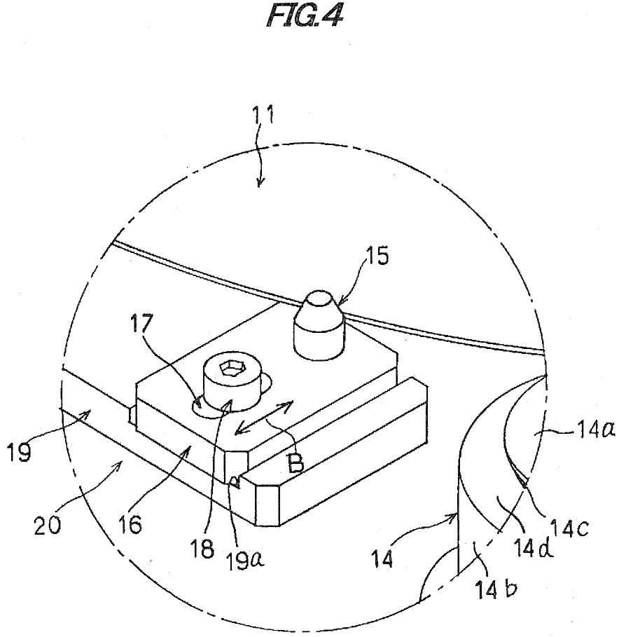

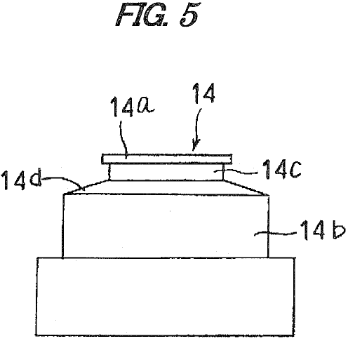

An embodiment of the invention is described below in reference to the appended drawings. FIGS. 3 to 5 show the construction of the substrate holding mechanism and the substrate carry-in mechanism of the substrate processing unit according to the invention. FIG. 3A is a plan view, FIG. 3B is a side view, FIG. 4 is a view showing the structure of the substrate guide mechanism, and FIG. 5 a view showing the structure of the roller of the substrate holding mechanism. In FIGS. 3 to 5, parts provided with the same symbols as those in FIG. 1 denote the same or corresponding parts.

As shown in drawings, the substrate processing unit is provided with the substrate holding mechanism 10 for holding the substrate 11 in a specified position. The substrate holding mechanism 10 has a plural number (four in drawings) of rollers 14. Each roller 14 has an integral structure of a small diameter 14a and a large diameter portion 14b as shown in FIG. 5 with the small diameter portion 14a formed above the large diameter portion 14b. The upper part of the large diameter portion 14b is made as a shoulder portion 14d, where a sloped surface slopes down toward its periphery. A recess 14c for engaging with the periphery of the substrate 11 is formed on the border between the shoulder portion 14d and the small diameter portion 14a. The rollers 14 are adapted to be rotatable by means of a turning mechanism (not shown).

Substrate guide mechanisms 20, 20 are placed near the periphery of the substrate 11 held with the substrate holding mechanism 10 in a specified holding position. As shown in FIG. 4, the substrate guide mechanism 20 has a slide plate 16 with a guide pin 15 installed in a standing manner. The slide plate 16 is made slidable in directions of the arrow B in a recess 19a formed in the guide mechanism attachment frame 19. The slide plate 16 has an elongated hole 17 so that, when a screw 18 is loosened, the slide plate 16 can be moved in directions of the arrow B. That makes the slide plate 16 move around the substrate 11 to come into contact with or move away from the substrate 11. It is possible to position the guide pin 15 near the periphery of the substrate 11 held in the specified holding position (a position apart by a specified distance from the periphery of the substrate 11) by tightening the screw 18.

The guide pin 15 is of a round rod shape with its upper part tapered off so that, even if the substrate 11 displaces during transferring, the displacement is absorbed as the substrate 11 slides down with its periphery in contact with the tapered surface. As shown in FIGS. 3A and 3B, the substrate 11 is carried in to the upper portion of the rollers 14 with the substrate carry-in mechanism 13 such as a robot arm. As the substrate carry-in mechanism 13 lowers, the substrate 11 is placed on and supported with the shoulder portions 14d of the four rollers 14. Even if the substrate 11 is displaced when it is carried in, the displacement is compensated (absorbed) as long as the substrate 11 is within the inscribed circle of the four guide pins 15, as the substrate 11 slides down with its periphery in contact with the tapered surface of the guide pin 15, and therefore, the substrate 11 is placed on the shoulder portions 14b of the four rollers 14. Here, the shoulder portions 14d of the four rollers 14 serve as the temporary placement table for temporarily placing the substrate 11 on.

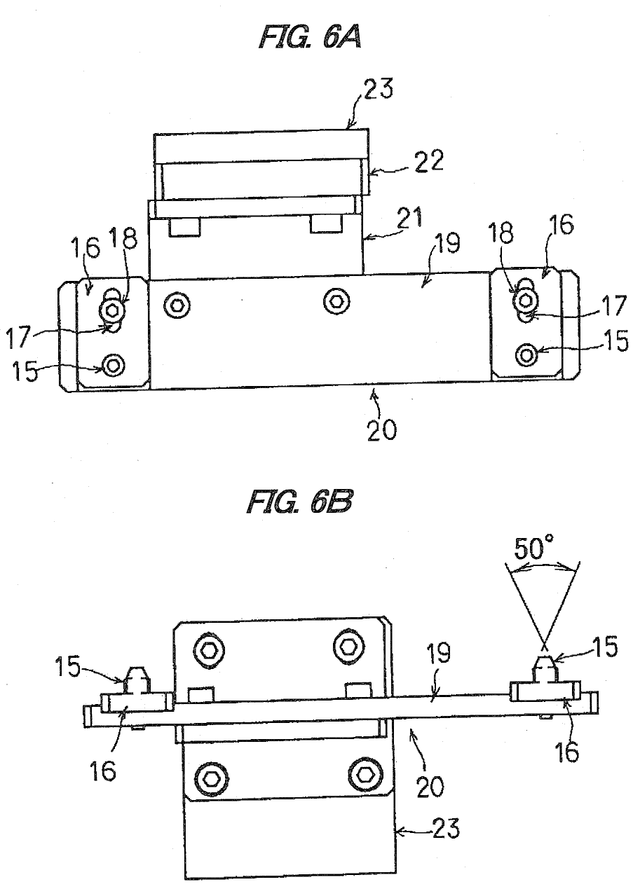

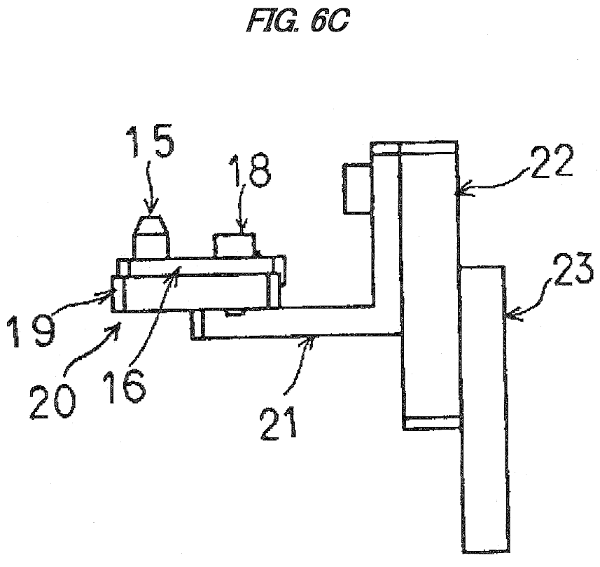

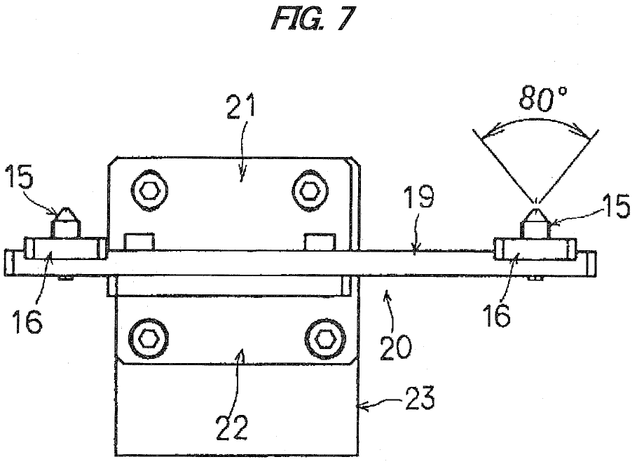

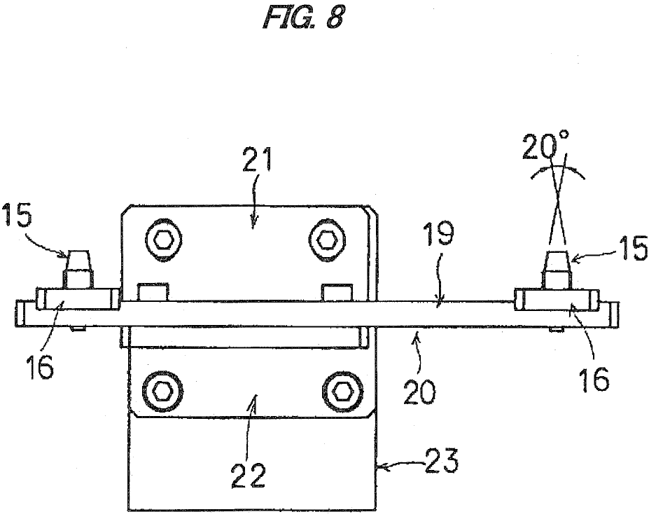

FIG. 6 shows the substrate guide mechanism 20 and its attachment structure, with FIG. 6A showing a plan view, FIG. 6B showing a front view, and FIG. 6C showing a side view. The guide mechanism attachment frame 19 of the substrate guide mechanism 20 is attached to the frame 23 of the substrate processing unit through brackets 21, 22. The position of the guide pins 15 can be adjustable by loosening the screw 18 and moving the slide plate 16 relative to the guide mechanism attachment frame 19. The taper portion of the guide pin 15 is made to slope by an angle of 50°. Incidentally, the slope angle of the taper portion of the guide pin 15 may be changed to 80° as shown in FIG. 7 or 200 as shown in FIG. 8 according to the condition of guiding the substrate 11. In case that the slope angle of the taper portion is made 80° or greater as shown in FIG. 7, while the degree of freedom in lowering the substrate 11 may be increased, the substrate 11 might be lowered aslant. In case that the slope angle of the taper portion is made 20° or less as shown in FIG. 8, the degree of freedom in lowering the substrate 11 decreases, and therefore, positioning accuracy of lowering the substrate 11 should be increased. While the guide pin 15 is assumed to be made of polyvinyl chloride (PVC) here, it is preferable to make at least the portion of the guide pin 15 that comes into contact with the substrate 11 using a plastic material such as PVC.

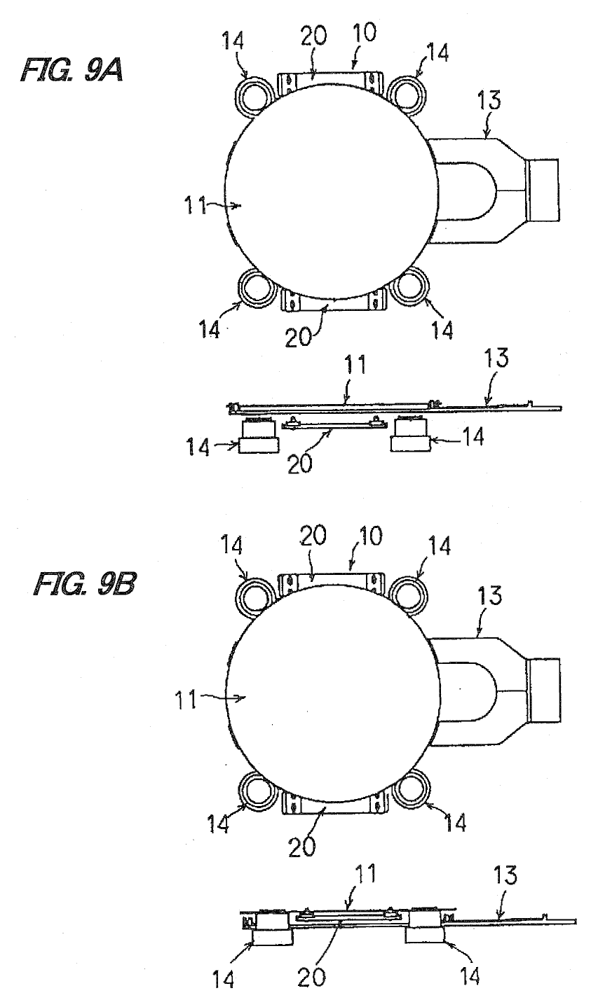

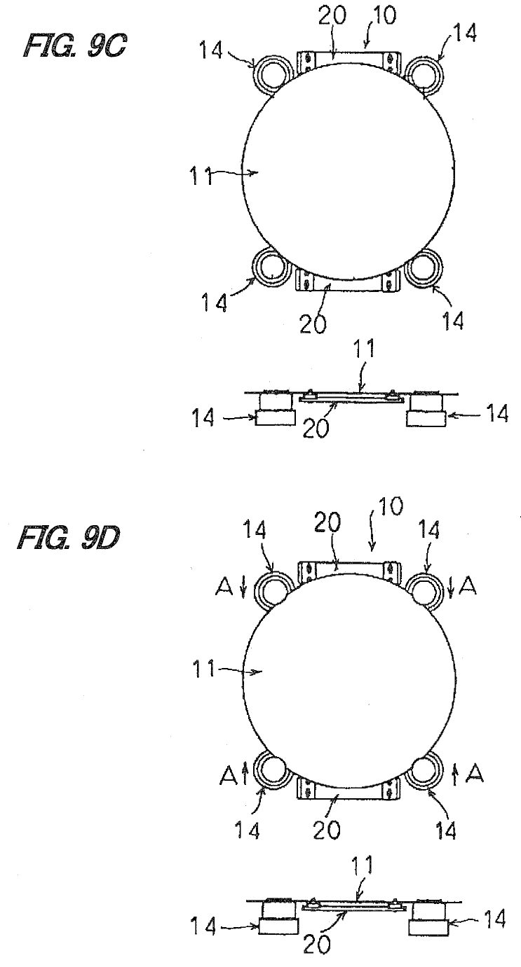

Next, actions of the substrate holding mechanism 10 and the substrate carry-in mechanism 13 are described in reference to FIG. 9. First, as shown in FIG. 9A, the substrate carry-in mechanism 13 such as a robot arm, which grips the substrate 11, is brought above the substrate holding mechanism 10 having the rollers 14. In this state, as the substrate carry-in mechanism 13 is lowered, the substrate 11, while being guided with the four guide pins 15 (see FIG. 3) of the substrate guide mechanisms 20, 20, is lowered and supported with the shoulder portions 14d of the four rollers 14 as shown in FIG. 9B, and is apart from the substrate carry-in mechanism 13. If the substrate 11 is displaced here, the position of the substrate 11 is corrected as it lowers while its periphery is in contact with the tapered surfaces of the guide pins 15, so that the substrate 11 is placed on the shoulder portions 14d of the four rollers 14. When the substrate 11 is released from being gripped with the substrate carry-in mechanism 13, there is a risk of the substrate 11 displacing as induced by the motion of a chuck or the like and coming off the support of the rollers 14. However, since the substrate 11 is restrained with the guide pins 15 from moving, it is prevented from coming off.

Since the substrate 11 is apart from the substrate carry-in mechanism 13 in the above state, the substrate 11 comes to the state of being supported on the four roller shoulder portions 14d of the substrate holding mechanism 10 with the substrate carry-in mechanism 13 being retracted as shown in FIG. 9C. In this state, as shown in FIG. 9D, the four rollers 14 are moved toward the substrate 11 in directions of arrows A, so that the periphery of the substrate 11 in sliding contact with the sloped surfaces of the shoulder portions 14d moves to engage with the recesses 14c of the rollers 14, and the substrate 11 is supported on its periphery from its sides with the four rollers 14. At this time, the slide plates 16 and guide pins 15 of the guide mechanisms 20 are apart by a certain distance from the underside and periphery of the substrate 11, respectively. Since the shoulder portion 14d of the roller 14 is formed as the sloped surface sloping down toward its periphery, the substrate 11 may also be supported from its sides with the rollers while the substrate 11 is temporarily placed on the shoulder portion 14d. In other words, the rollers 14 may be moved while the substrate carry-in mechanism 13 is lowered. Then, at the time the substrate 11 contacts the sloped surface of the shoulder portion 14d, the substrate 11 is in the state of being temporarily placed on the shoulder portions 14d of the rollers 14. As the rollers 14 continue to move further, the substrate 11 comes to be supported from its sides with the rollers 14. Therefore, motions from gripping the substrate 11 with the substrate carry-in mechanism 13 to the temporary placement on the shoulder portions 14d of the rollers 14 and to the supporting it from its sides with the rollers 14 are made continuous and smooth. The continuous, smooth motion as described above makes it possible to reduce required time in comparison with conventional process in which the substrate is lowered to and stopped at a specified height with the substrate carry-in mechanism, it is supported from its sides by the motion of the rollers, and the substrate carry-in mechanism is then further lowered and retracted. This contributes to the increase in throughput. Further, since the shoulder portion 14d is made as the sloped surface, contact area between the substrate 11 and the roller 14 is small, so that the possibility of the substrate 11 being contaminated is reduced.

As described above, the substrate guide mechanisms 20, 20 respectively having the two guide pins are placed on both sides of the holding position of the substrate 11 held with the substrate holding mechanism 10. As the substrate carry-in mechanism 13 holding the substrate 11 simply moves to above the substrate holding position of the substrate holding mechanism 10 and then lowers, the substrate 11 is supported on the shoulder portions 14d of the four rollers 14 and detached from the substrate carry-in mechanism 13. Therefore, the substrate carry-in mechanism 13 can be thereafter released, immediately retracted, and moved to the next step. Incidentally, while this embodiment is described on the assumption that the substrate guide mechanism 20 has one slide plate 16 having two guide pins 15 and being capable of slide, the structure of the substrate guide mechanism 20 is not limited to the above. For example, a plural number of guide pins 15 may be directly installed on the frame 23 of the substrate holding mechanism 10 or a processing tank 30 in a standing manner. In that case, the substrate guide mechanism 20 is identical with the guide pins 15. In other words, any mechanism provided with the guide pins 15 to guide the substrate 11 to a specified position when the substrate 11 is carried in to the substrate holding mechanism 10 can be the substrate guide mechanism 20. Incidentally, it is preferable to provide the slide plate 16 that is movable as this embodiment so as to easily adjust the position where the substrate 11 is guided to and to cope with the change in the size of the substrate 11.

The substrate 11 having undergone the specified process in the state of its periphery supported from its sides with the four rollers 14 of the substrate holding mechanism 10 in the holding position remains in the state supported from its sides with the four rollers 14 as shown in FIG. 9D. When the rollers 14 are moved in the directions apart from the substrate 11 (in the directions opposite the arrows A), the substrate 11 comes to the state of being supported on the shoulder portions 14d of the four rollers 14 as shown in FIG. 9C. In this state, when a substrate carry-out mechanism such as a robot hand is brought below the substrate holding mechanism 10 and raised, the substrate 11 supported on the shoulder portions 14d of the four rollers 14 is held with the substrate carry-out mechanism. When the substrate carry-out mechanism is retracted, the substrate 11 is carried out. Since the shoulder portion 14d of the roller 14 is formed as the sloped surface sloping down toward its periphery, the substrate 11 can also be supported with the substrate carry-out mechanism while the substrate 11 is placed temporarily on the shoulder portion 14d. In other words, the substrate carry-out mechanism may be raised while the rollers 14 are moved. Then, as the rollers 14 move, the substrate 11 is placed temporarily on the sloped surface of the shoulder portions 14d. During that time, the substrate carry-out mechanism holds the substrate 11 and carries it out of the substrate holding mechanism 10. The motion of the rollers 14, and rise and retraction of the substrate carry-out mechanism are made simultaneously and continuously. Therefore, the motions from supporting the substrate 11 from its sides with the rollers 14 to the temporary placement of the substrate 11 on the shoulder portions 14d, and carrying it out with the substrate carry-out mechanism are made continuous and smooth. The continuous, smooth motion described above makes it possible to reduce the required time in comparison with the time required for the conventional process for the change from supporting the substrate from its sides to temporarily placing it by the roller motion, rise and stop of the substrate carry-out mechanism, holding the substrate by the further motion of the substrate carry-out mechanism, and further rise and retraction of the substrate carry-out mechanism. This contributes to the increase in throughput. Incidentally, while the substrate carry-out mechanism is assumed typically to be the same as the substrate carry-in mechanism 13, any known, different mechanism may be used.

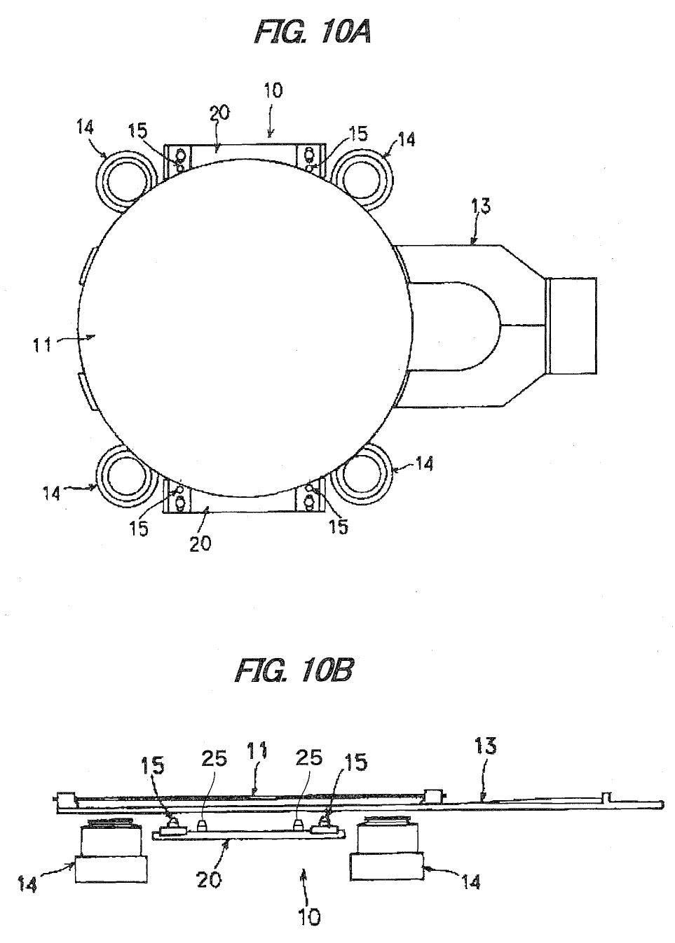

While it is assumed in the above example that the shoulder portions 14d of the four rollers 14 of the substrate holding mechanism 10 are used as the temporary placement table for placing the substrate 11 on, the temporary placement table is not limited to that. For example as shown in FIGS. 10-12, a plural number of projections or pins 25 (hereinafter called the temporary placement pins 25) may be provided inside the guide pins 15 of the slide plate 16, with the temporary placement pins 25 being in height the same as, or slightly greater than the shoulder portion 14d and slightly smaller than the recess of the roller 14, or the same as the recess of the roller 14. It may be formed to place the substrate 11 carried in with the substrate carry-in mechanism 13 or released from the substrate holding mechanism 10 on the temporary placement pins 25. Providing the temporary placement pins 25 separately from the rollers 14 as described above results in that the temporary placement pins 25 do not contact the substrate 11 when the rollers 14 support the substrate 11 from its sides, so that the substrate 11 is not damaged by scratching or the like.

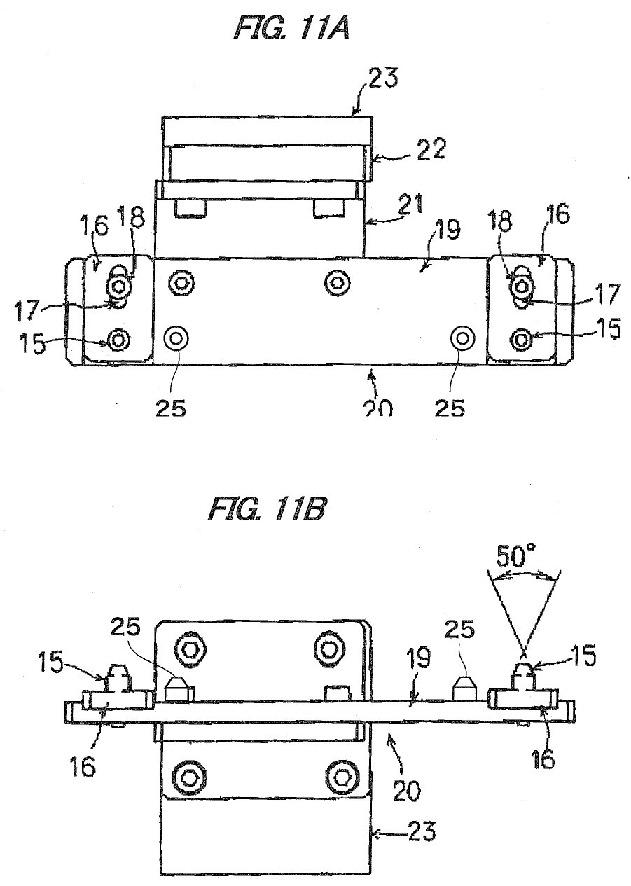

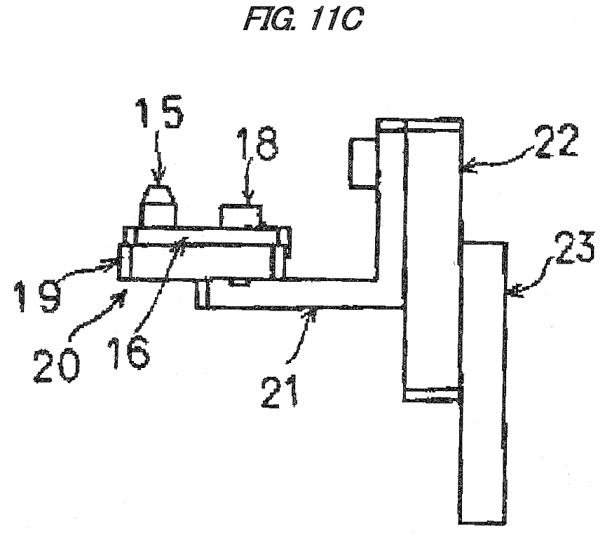

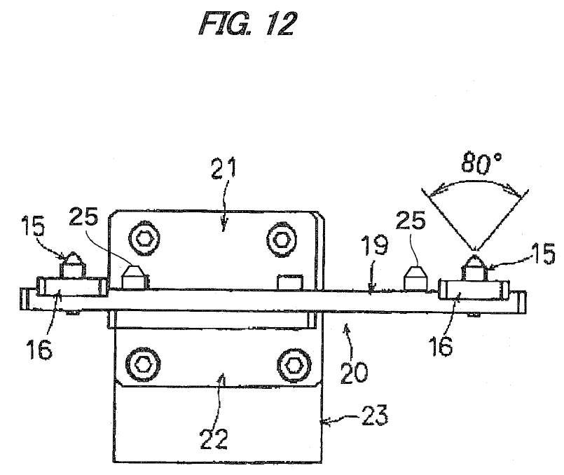

FIG. 10 shows the structure of the substrate holding mechanism and the substrate carry-in mechanism provided with the temporary placement pins 25 according to the present invention, with FIG. 10A in plan view, and FIG. 10B in side view. FIG. 11 shows the substrate guide mechanism 20 provided with the temporary placement pins 25 and their attachment structure, with FIG. 11A in plan view, FIG. 11B in front view, and FIG. 11C in side view. FIG. 12 shows an example of construction of the substrate guide mechanism 20 of the substrate processing unit provided with the temporary placement pins 25.

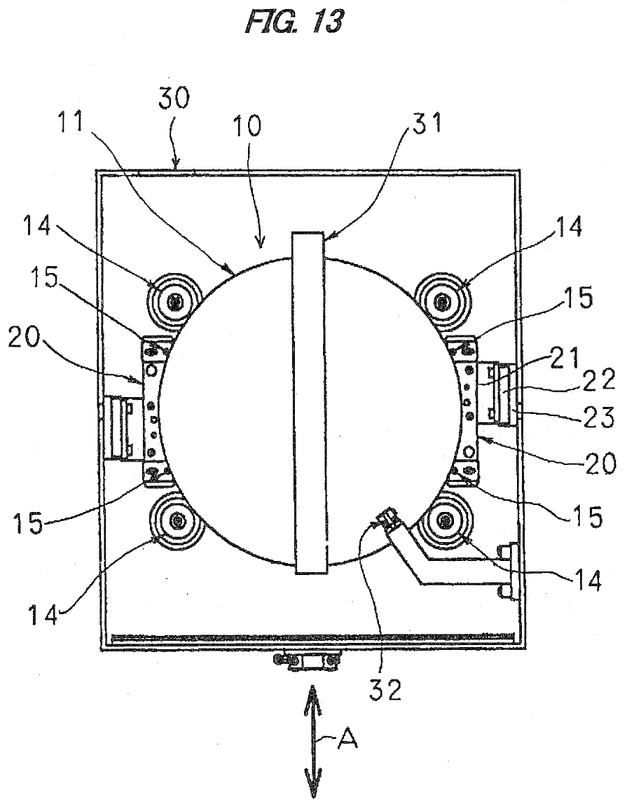

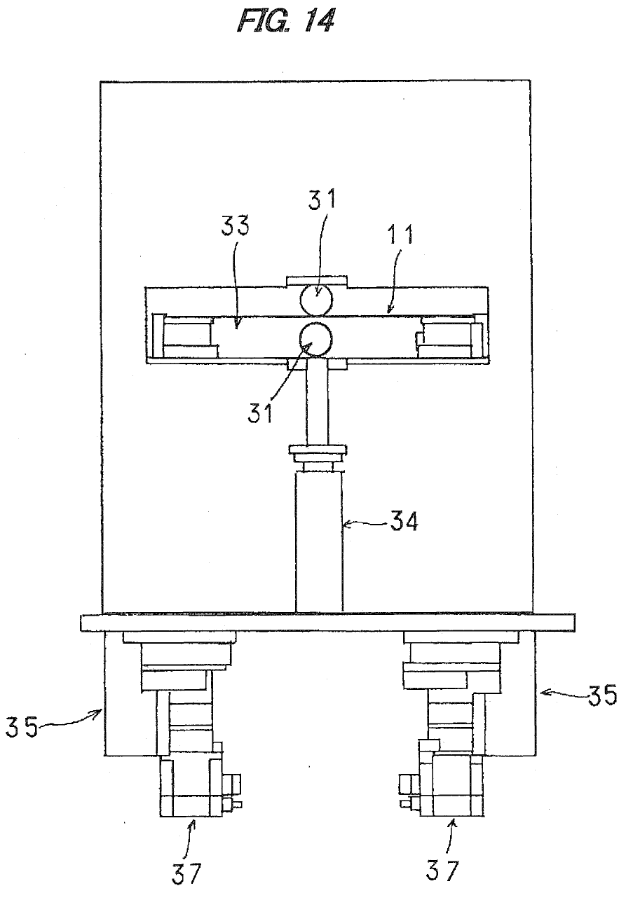

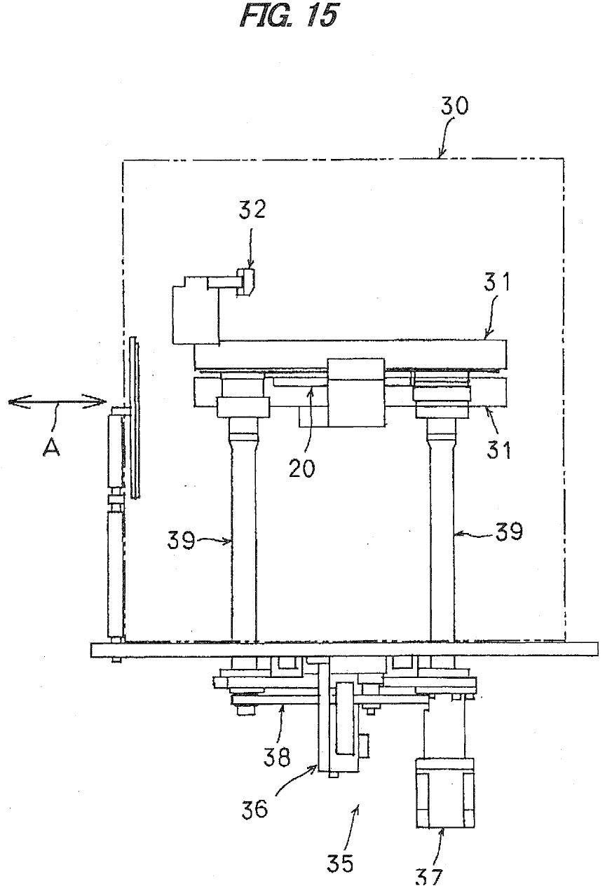

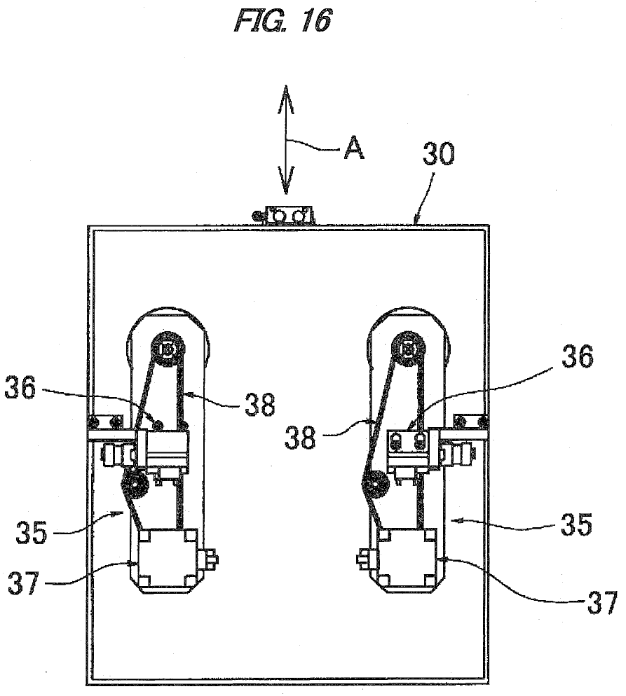

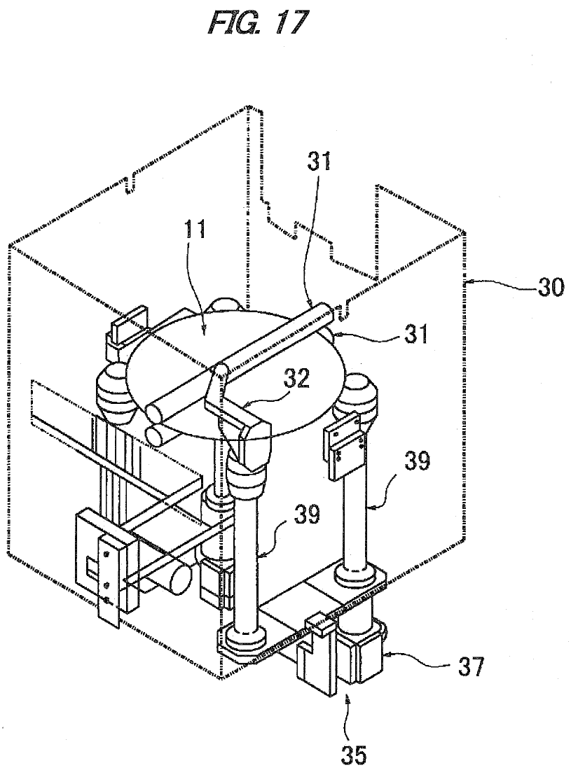

FIGS. 13 to 17 show examples of structure of the substrate processing unit according to the invention. FIG. 13 shows the planar construction in plan view. FIG. 14 shows the outside appearance construction in front view. FIG. 15 shows the inside construction in side view. FIG. 16 shows the rear side construction in rear view. FIG. 17 shows the entire construction in perspective view. The substrate processing unit is provided with a processing tank 30, inside of which is provided with the substrate holding mechanism 10 having the four rollers 14 shown in FIG. 3. The substrate 11, with its periphery supported from its sides with the four rollers 14 of the substrate holding mechanism 10, is rotated by the rotation of the rollers 14. The substrate guide mechanisms 20, 20 are placed so that the guide pins 15 are located in the vicinity of the periphery of the substrate 11 held in a specified position with the substrate holding mechanism 10.

The guide mechanism attachment frame 19 of the substrate guide mechanisms 20, 20 is attached as shown in FIG. 6 through brackets 21, 22 to the frame 23 of the processing tank 30. Roll-shaped brushes 31 come in contact with upper and lower surfaces of the substrate 11 supported from its sides and held with the four rollers 14 of the substrate holding mechanism 10. Cleansing nozzles 32 placed in the upper and lower direction (the lower nozzle 32 is not shown) supply cleansing liquid to the upper and lower surfaces of the substrate 11, so that the upper and lower surfaces of the substrate 11 are cleansed by the relative motion between the rotating roll-shaped brushes 31 and the substrate 11 rotating with the rotation of the rollers 14.

The processing tank 30 has on its front face a transfer port 33 through which the substrate 11 is to be carried in and out. The transfer port 33 has a shutter (not shown) for opening and closing the port and operated with a shutter operation cylinder 34. Two roller drive mechanisms 35 are provided below the processing tank 30 for rotating the four rollers 14, two each on left and right sides, and for moving the rollers 14 in the directions of the arrows A shown in FIG. 9D to hold the substrate 11 from its sides and in the opposite directions. The substrate 11 can be carried out through the opened transfer port 33 in the direction of the arrow A.

Each roller drive mechanism 35 is provided with a chuck operation cylinder 36 for supporting the substrate 11 from its sides and releasing it and with a motor 37 for rotating the rollers. By the operation of the left and right chuck operation cylinders 36, the rollers 14 are moved in the directions of the arrows A or in the opposite directions, so that the substrate 11 is supported from its sides or released. As the motors 37 for rotating the left and right rollers are started, the four rollers 14, two each on left and right hand, are rotated in the same direction through a belt 38 and a spindle 39 to rotate the substrate 11.

As for the substrate cleansing process unit of the above structure, the substrate 11 carried in through the transfer port 33 by means of the substrate carry-in mechanism 13 (See FIG. 3) such as a robot arm is supported from its sides with the four rollers 14 in the sequence shown in FIGS. 9A through 9D, and cleansed. When the cleansing process is finished, the substrate 11 is carried out of the processing tank 30 in the sequence opposite that shown in FIGS. 9A through 9D.

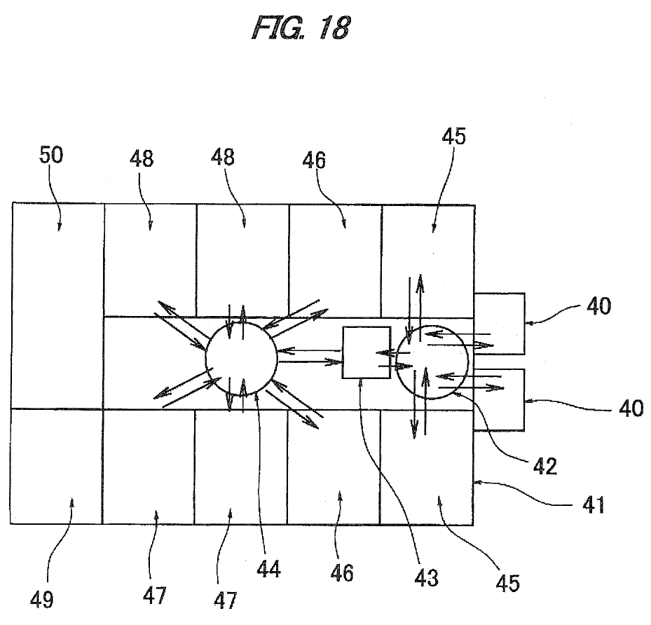

FIG. 18 is a plan view showing the planar construction example of the substrate processing apparatus (plating apparatus) provided with the substrate cleansing process unit of the structure shown in FIGS. 13 through 17. This substrate processing apparatus is provided with an apparatus frame 41 of a rectangular shape with a detachable transfer box such as an SMIF box holding a large number of substrates such as semiconductor wafers. In the central interior of the apparatus frame 41, the first substrate transfer robot 42, a temporary placement table 43, and the second substrate transfer robot 44 are placed in line.

On its both sides, a pair of substrate cleanse-drying units 45, a substrate cleansing unit 46, a pre-plating processing unit 47, and a pre-plating processing and plating unit 48 are placed. Further on the opposite side of the transfer box 40, there are provided a pre-plating processing liquid supplying section 49 for supplying pre-plating processing liquid to the pre-plating processing unit 47, and a plating liquid supplying section 50 for supplying plating liquid to the pre-plating processing and plating unit 48. The substrate cleansing process unit of the structure shown in FIGS. 13 through 17 is used as the structure cleansing unit 46.

The substrate processing apparatus of the structure shown in FIG. 18 is placed in a clean room so that air does not flow from the apparatus frame 41 into the clean room. Further, a downward fresh air flow (down-flow) is formed within the apparatus frame 41.

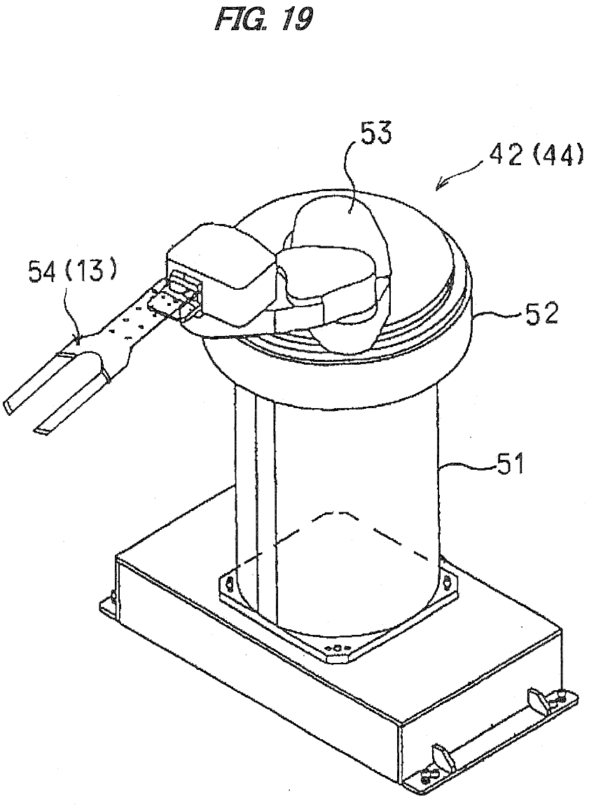

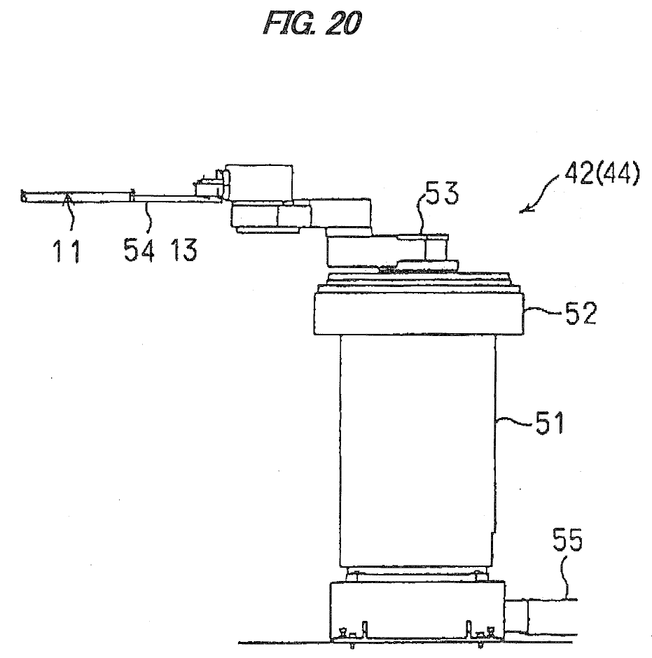

FIGS. 19 through 21 show the construction of the first substrate transfer robot 42. The second substrate transfer robot 44 is the same or similar in construction as the first substrate transfer robot 42. The first substrate transfer robot 42 is of the so-called stationary type robot having a vertically extendable drum 51, a rotary drive section 52 attached to the top of the drum 51, and a robot arm 53 attached to the rotary drive section 52 to be capable of extending and contracting horizontally. A hand 54 (the substrate carry-in mechanism 13 in FIG. 3) for holding the substrate 11 is attached to the tip of the robot arm 53.

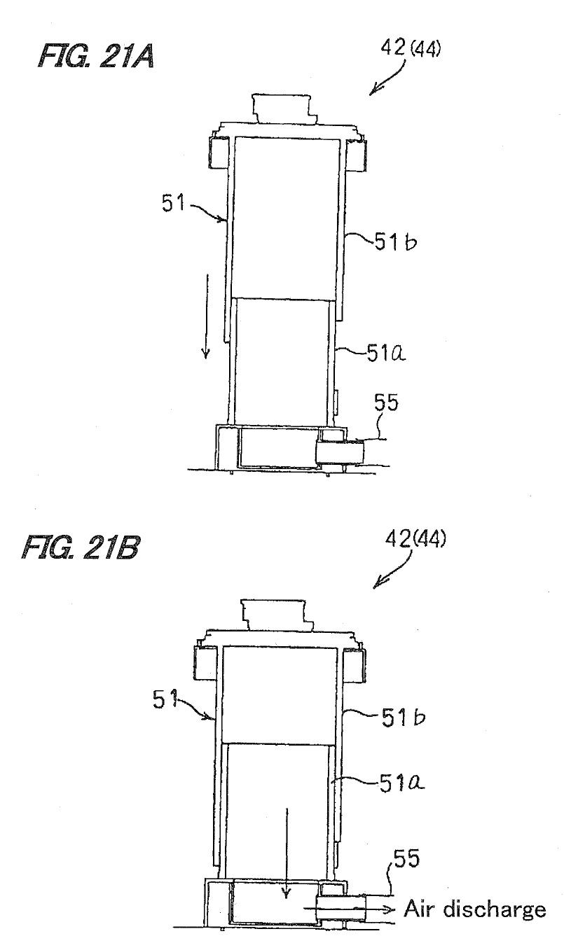

As shown in FIG. 21, the drum 51 is made up of a hollow inner drum 51a and a hollow outer drum 51b, to constitute a type with one nesting inside the other, to be freely extended or contracted. An exhaust duct (exhaust section) 55 for communicating with the interior of the hollow inner and outer drums 51a and 51b is connected to the bottom of the drum 51, so that air within the first substrate transfer robot 42 is discharged out through the exhaust duct 55 and recovered.

Thus, for example air discharged from the interior of the first substrate transfer robot 42 resulting from vertical motion by extension and contraction of the drum 51 of the first substrate transfer robot 42 is prevented from leaking through the gap in particular between the inner drum 51a and the outer drum 51b to the outside of the first substrate transfer robot 42. Therefore, it is possible to stabilize the air flow in the vicinity of the first substrate transfer robot 42 and prevent the substrate 11 from being contaminated with particles.

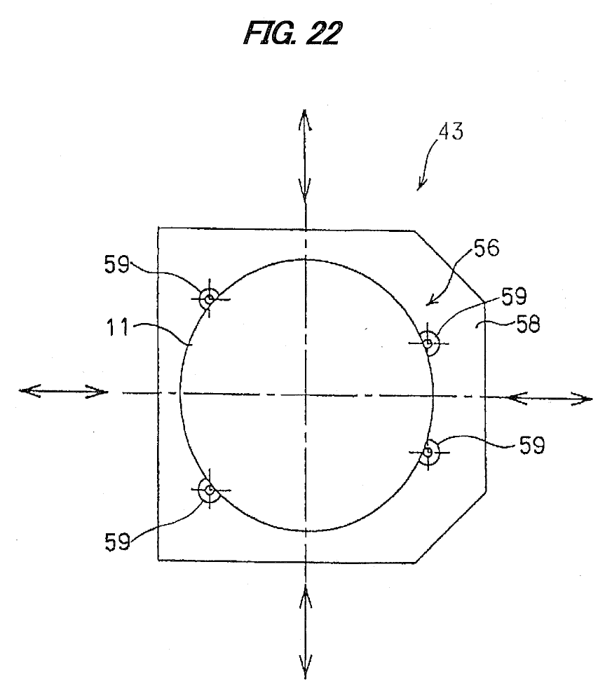

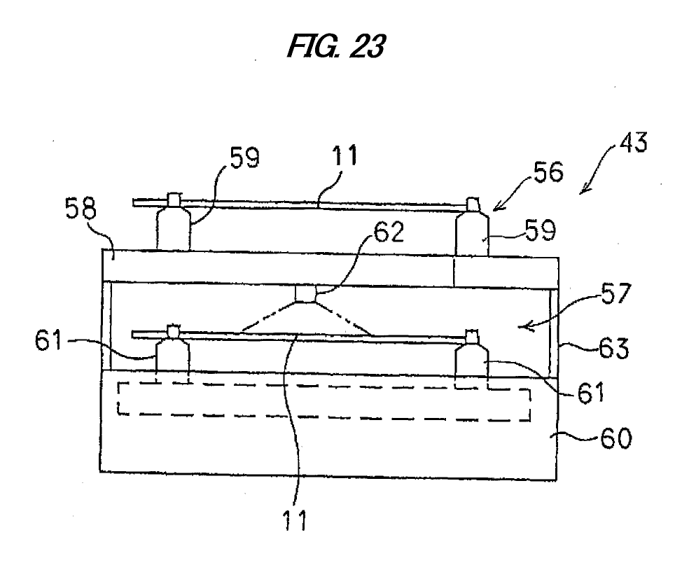

FIGS. 22 and 23 show the temporary placement table 43. The temporary placement table 43 is adapted to carry in and out the substrate 11 to and from one of the first substrate transfer robot 42 side and the second substrate transfer robot 44 side. It is understood that it may be adapted to carry in and out the substrate in any direction. Providing the temporary placement table 43 for placing the substrate 11 on in this way between the first substrate transfer robot 42 and the second substrate transfer robot 44 makes it possible to transfer the substrate 11 efficiently within the apparatus frame 41, and to use stationary robots as the first substrate transfer robot 42 and the second substrate transfer robot 44. Thus, reduction of the cost of the apparatus as a whole can be achieved.

The temporary placement table 43 is provided with an upper level, dry-use substrate holding section 56 and a lower level, wet-use substrate holding section 57, where the upper and lower positions are separated with a partition plate 58. The dry-use substrate holding section 56 has a plural number of support pins 59 installed in a standing manner on the partition plate 58 along the periphery of the substrate 11 to position and hold the substrate 11 through tapered portions formed on the upper portions of the support pins 59. The wet-use substrate holding section 57 likewise has a plural number of support pins 61 installed in a standing manner on the base plate 60 along the periphery of the substrate 11 to position and hold the substrate 11 through tapered portions formed on the upper portions of the support pins 61.

A pure water spray nozzle 62 as a mechanism for preventing the substrate 11 from drying up is attached to the underside of the partition plate 58. The pure water spray nozzle 62 prevents the substrate 11 from drying up by spraying pure water to the surface (upper surface) of the substrate 11 supported with the support pins 61 of the wet-use substrate holding section 57. Further, freely movable shutters 63 for preventing the pure water from leaking out, which is sprayed off the pure water spray nozzle 62 to the substrate 11, are provided between the partition plate 58 and the base plate 60.

The substrate 11 transferred with the first substrate transfer robot 42 is positioned and held with the support pins 59 of the dry-use substrate holding section 56 of the upper level. The substrate 11, after a series of process steps, is held and transferred with the second substrate transfer robot 44 and positioned with the support pins 61 of the wet-use substrate holding section 57 of the lower level. Whether or not the substrate 11 is held is sensed with a sensor (not shown).

In the substrate processing apparatus of the above construction, the first substrate transfer robot 42 takes one substrate 11 out of the transfer box 40 and transfers it to the dry-use substrate holding section 56 of the temporary placement table 43. The substrate 11 is held with the dry-use substrate holding section 56. The substrate 11 held with the dry-use substrate holding section 56 is transferred with the second substrate transfer robot 44 to the pre-plating processing unit 47. Pre-plating process is applied to the substrate 11 in the pre-plating processing unit 47. The substrate 11 of which the pre-plating process is finished, is transferred with the second substrate transfer robot 44 to the pre-plating processing and plating unit 48 where the pre-plating process and plating process are applied. The substrate 11 of which plating process is finished, is transferred with the second substrate transfer robot 44 to the substrate cleansing unit 46 of the construction shown in FIGS. 13 to 17.

In the substrate cleansing unit 46, upper and lower surfaces of the substrate 11 are cleansed using the roll-shaped brushes 31 to remove particles and foreign matter adhering to the substrate 11. The substrate 11 made free from particles and foreign matter is transferred with the second substrate transfer robot 44 to the wet-use substrate holding section 57 of the temporary placement table 43 and held with the wet-use substrate holding section 57. While the substrate 11 is being held as described above, it is prevented from drying up by spraying pure water to the substrate 11.

The first substrate transfer robot 42 takes the substrate 11 out of the wet-use substrate holding section 57 of the temporary placement table 43 and transfers it to the substrate cleanse-drying unit 45 where the surfaces of the substrate 11 undergo chemical cleansing and pure water cleansing, followed by spin-drying. After the spin-drying, the substrate 11 is returned with the first substrate transfer robot 42 into the transfer box 40. Thus, the processing of the substrate 11 is finished.

The reference numerals used in the above description are collectively shown below for reference.
10 substrate holding mechanism
11 substrate
12 roller
13 substrate carry-in mechanism
14 roller
15 guide pin
16 slide plate
17 elongated hole
18 screw
19 guide mechanism attachment frame
20 substrate guide mechanism
21 bracket
22 bracket
23 frame
25 temporary placement pin
30 processing tank
31 roll-shaped brush
32 cleansing nozzle
33 transfer port
34 shutter operation cylinder
35 roller drive mechanism
36 chuck operation cylinder
37 motor for rotating the rollers
38 belt
39 spindle
40 transfer box
41 apparatus frame
42 first substrate transfer robot
43 temporary placement table
44 second substrate transfer robot
45 substrate cleanse-drying unit
46 substrate cleansing unit
47 pre-plating processing unit
48 pre-plating processing and plating unit
49 pre-plating processing liquid supplying section
50 plating liquid supplying section
51 drum
52 rotary drive section
53 robot arm
54 hand
55 exhaust duct
56 dry-use substrate holding section
57 wet-use substrate holding section
58 partition plate
59 support pin
60 base plate
61 support pin
62 pure water spray nozzle
63 shutter

The embodiments of the present invention have been described as above. However, the invention is not limited to the embodiment described above but may be modified in various ways within the scope of the claims and the technical ideas described in the specification and the appended drawings.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising”, “having”, “including” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1-9. (canceled)

10. A substrate processing unit comprising:
a substrate holding mechanism for holding a substrate in a specified position, the substrate holding mechanism having a plural number of rollers on a periphery of the substrate in a holding position, the plural number of rollers being adapted to hold the substrate by supporting the periphery of the substrate from sides thereof in vicinity of the holding position;
a processing mechanism for applying a specified process to the substrate held with the substrate holding mechanism; and
a substrate guide mechanism provided with a guide pin for guiding the substrate to vicinity of the holding position,
wherein the roller each has an integral structure made up of a large diameter portion and a small diameter portion formed above the large diameter portion, with an upper portion of the large diameter portion having a shoulder portion for temporarily placing the substrate on in transfer of the substrate, and
the shoulder portion is formed with a sloped surface sloping down toward the periphery of the substrate.

11. A substrate processing unit comprising:
a substrate holding mechanism for holding a substrate in a specified position, the substrate holding mechanism having a plural number of rollers on a periphery of the substrate in a holding position, the plural number of rollers being adapted to hold the substrate by supporting the periphery of the substrate from sides thereof in vicinity of the holding position;
a processing mechanism for applying a specified process to the substrate held with the substrate holding mechanism; and
a substrate guide mechanism provided with a guide pin for guiding the substrate to vicinity of a holding position, the substrate guide mechanism having a temporary placement tool for temporarily placing the substrate on in transfer of the substrate,
wherein the roller each has an integral structure made up of a large diameter portion and a small diameter portion formed above the large diameter portion with an upper portion of the large diameter portion having a shoulder portion formed with a sloped surface sloping down toward periphery of the substrate.

12. The substrate processing unit as recited in claim 10,
wherein the substrate has a disk shape, and
the guide pins of the substrate guide mechanism are placed around the substrate held in the holding position, and have a function of guiding the substrate to the vicinity of the holding position even if the substrate displaces when being held or released.

13. The substrate processing unit as recited in claim 11,
wherein the substrate has a disk shape, and
the guide pins of the substrate guide mechanism are placed around the substrate held in the holding position, and have a function of guiding the substrate to the vicinity of the holding position even if the substrate displaces when being held or released.

14. The substrate processing unit as recited in claim 10,
wherein the upper portion of the guide pin of the substrate guide mechanism is tapered off to provide a function of absorbing a displacement of the substrate in transfer thereof.

15. The substrate processing unit as recited in claim 11,
wherein the upper portion of the guide pin of the substrate guide mechanism is tapered off to provide a function of absorbing a displacement of the substrate in transfer thereof.

16. The substrate processing unit as recited in claim 10,
wherein the guide pins of the substrate guide mechanism are placed in positions apart from the periphery of the substrate to avoid interference with the substrate when the substrate in the holding position is processed.

17. The substrate processing unit as recited in claim 11,
wherein the guide pins of the substrate guide mechanism are placed in positions apart from the periphery of the substrate to avoid interference with the substrate when the substrate in the holding position is processed.

18. The substrate processing unit as recited in one of claim 10,
wherein the rollers are adapted to be rotated with a rotary mechanism, and
the substrate is rotated by rotation of the rollers.

19. The substrate processing unit as recited in claim 11,
wherein the rollers are adapted to be rotated with a rotary mechanism, and
the substrate is rotated by rotation of the rollers.

20. A substrate transfer method for holding a substrate carried in with a substrate carry-in mechanism in a specified holding position and carrying out the substrate after a specified process comprising the steps of:
guiding the substrate carried in to vicinity of the holding position with guide pins as the substrate carry-in mechanism lowers;
placing the substrate on a temporary placement portion to be released from the substrate carry-in mechanism;
holding the substrate released from the substrate carry-in mechanism with a plural number of rollers by supporting a periphery of the substrate from sides thereof in the holding position;
applying a specified process to the substrate held;
releasing the substrate applied the specified process from holding to be placed on the temporary placement portion; and
carrying out the substrate placed on the temporary placement portion,
wherein the roller each has an integral structure made up of a large diameter portion and a small diameter portion formed above the large diameter portion, and an upper portion of the large diameter portion has a shoulder portion formed with a sloped surface sloping down toward the periphery of the substrate, and
wherein the substrate placed on the shoulder portion is held and supported from sides thereof as the plural number of rollers move toward the substrate, and released and placed on the shoulder portion as the rollers move in the opposite direction.

21. A substrate cleansing process unit comprising:
a plural number of rollers for holding a substrate in a specified holding position, the rollers having an integral structure made up of a large diameter portion and a small diameter portion formed above the large diameter portion, an upper portion of the large diameter portion having a shoulder portion permitting the substrate in transfer to be temporarily placed on, the shoulder portion being formed with a sloped surface sloping down toward a periphery of the substrate, to hold the substrate by supporting the periphery of the substrate from sides thereof in vicinity of the holding position;
a guide pin for guiding the substrate to the vicinity of the holding position;
a cleansing nozzle for supplying cleansing liquid to the substrate held with the rollers; and
a brush for coming into contact with a surface of the substrate held with the rollers.

22. A substrate plating apparatus comprising:
a pre-plating processing and plating unit for applying a pre-plating process and a plating process to a substrate;
the substrate cleansing process unit as recited in claim 21 for cleansing the substrate having undergone the pre-plating process and the plating process with the pre-plating processing and plating unit; and
a substrate transfer robot for transferring the substrate having undergone the pre-plating process and the plating process from the pre-plating processing and plating unit to the substrate cleansing process unit, and carrying the substrate out of the substrate cleansing process unit.
